(19) United States
(12) Patent Application Publication
(10) Pub. No.: US 2007/0215328 A1
(43) Pub. Date: Sep. 20, 2007

(54) Coated heat sink

(76) Inventors: Ying-Lin Hsu, Chung-Ho City (TW); Kun-Feng Tu, Chung-Ho City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/702,139

(22) Filed: Feb. 5, 2007

(30) Foreign Application Priority Data
Mar. 17, 2006 (TW) 95204528

(51) Int. Cl. H05K 7/20

(52) U.S. Cl. 165/104.33; 361/700; 165/80.3

(57) ABSTRACT

A coated heat sink includes: a copper base seat, an aluminum heat-dissipating seat, a plurality of heat pipes, a solder, a heat-conducting adhesive glue, and a plurality of heat-dissipating fins. The aluminum heat-dissipating seat disposes on top of the copper base seat. The heat pipes dispose on the top of the copper base seat. The solder respectively forms on contact surfaces among the copper base seat and the heat pipes for joining the copper base seat and the heat pipes together. The glue respectively forms on contact surfaces between the copper base seat and the aluminum heat-dissipating seat and among the aluminum heat-dissipating seat and the heat pipes for joining the copper base seat and the aluminum heat-dissipating seat together, and the aluminum heat-dissipating seat and the heat pipes together. The fins dispose over the aluminum heat-dissipating seat, and the fins stack together and compactly joint with the heat pipes.

### BACKGROUND OF THE INVENTION

1. Field of the Invention

The present invention relates to a coated heat sink, and particularly relates to a heat sink having an aluminum heat-dissipating seat for compactly joining with a copper base seat and a plurality of heat pipes.

2. Description of the Related Art

Referring to FIGS. 1 and 2, a known heat sink includes a nickel-plated heat-dissipating seat 1a, a copper base seat 2a, a plurality of aluminum pieces 3a, and a plurality of heat pipes 4a. The nickel-plated heat-dissipating seat la is made of aluminum, and the copper base seat 2a is a copper piece.

Moreover, the nickel-plated heat-dissipating seat la is welded on the copper base seat 2a. The copper base seat 2a has two sides screwed on the nickel-plated heat-dissipating seat la by two screws 20a, in order to firmly fix the nickel-plated heat-dissipating seat 1a on to the copper base seat 2a. Furthermore, the aluminum pieces 3a are disposed over the nickel-plating heat-dissipating seat 1a. The heat pipes 4a penetrate the aluminum pieces 3a respectively, and a bottom side of each the heat pipe 4a is welded on to the copper base seat 2a. The heat from the nickel-plating heat-dissipating seat la is dissipated by the heat-conducting property of the heat pipes 4a. However, the assembly of the known heat sink is complex. Additionally, when both the aluminum and the copper need to be jointed, the nickel needs to be plated on the aluminum first, such as in the above-mentioned nickel-plated heat-dissipating seat. Hence, the cost of the known heat sink is increased.

### SUMMARY OF THE INVENTION

The present invention provides a coated heat sink. The present invention provides a solder respectively formed on contact surfaces among a copper base seat and a plurality of heat pipes for compactly joining the copper base seat and the heat pipes with each other. Moreover, the present invention provides a heat-conducting adhesive glue respectively formed on contact surfaces between the copper base seat and the aluminum heat-dissipating seat and among an aluminum heat-dissipating seat and the heat pipes for compactly joining the copper base seat and the aluminum heat-dissipating seat with each other, and the aluminum heat-dissipating seat and the heat pipes with each other. Hence, the present invention omits the nickel-plating process and thereby reduces the manufacturing cost.

A first aspect of the present invention is a coated heat sink, including: a copper base seat, an aluminum heat-dissipating seat, a plurality of heat pipes, a solder, a heat-conducting adhesive glue, and a plurality of heat-dissipating fins. The aluminum heat-dissipating seat is disposed on a top portion of the copper base seat. The heat pipes are respectively disposed on the top portion of the copper base seat. The solder is respectively formed on contact surfaces among the copper base seat and the heat pipes for compactly joining the copper base seat and the heat pipes together. The heat-conducting adhesive glue is respectively formed on contact surfaces between the copper base seat and the aluminum heat-dissipating seat and among the aluminum heat-dissipating seat and the heat pipes for compactly joining the copper base seat and the aluminum heat-dissipating seat together, and the aluminum heat-dissipating seat and the heat pipes together, respectively. The heat-dissipating fins are disposed over the aluminum heat-dissipating seat, and the heat-dissipating fins are stacked together other and compactly jointed with the heat pipes.

A second aspect of the present invention is a coated heat sink, including: a copper base seat, a heat-conducting unit, a plurality of heat pipes, a solder, and a heat-conducting adhesive glue. The heat-conducting unit has an aluminum heat-dissipating seat disposed on a top portion of the copper base seat and a plurality of fins disposed on a top side of the aluminum heat-dissipating seat. The heat pipes are respectively disposed on the top portion of the copper base seat and compactly join the fins together. The solder is respectively formed on contact surfaces among the copper base seat and the heat pipes for compactly joining the copper base seat and the heat pipes together. The heat-conducting adhesive glue is respectively formed on contact surfaces between the copper base seat and the aluminum heat-dissipating seat and among the aluminum heat-dissipating seat and the heat pipes for compactly joining the copper base seat and the aluminum heat-dissipating seat together, and the aluminum heat-dissipating seat and the heat pipes together, respectively.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a front, schematic view of a heat sink of the prior art;

FIG. 2 is a bottom, schematic view of a heat sink of the prior art;

FIG. 3 is a front, schematic view of a coated heat sink according to the first embodiment of the present invention; and

FIG. 4 is a front, schematic view of a coated heat sink according to the second embodiment of the present invention.

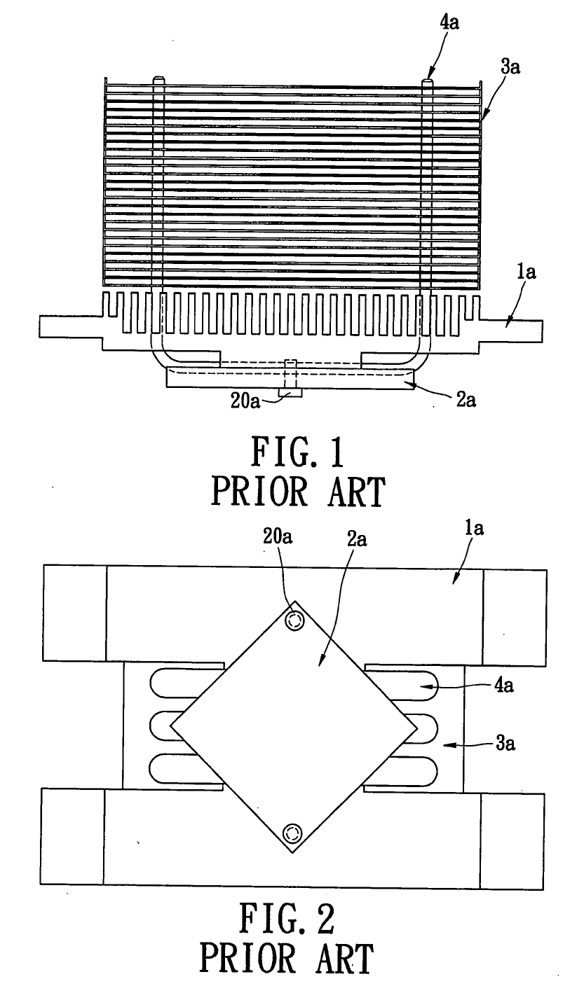

### DETAILED DESCRIPTION OF PREFERRED BEST MOLDS

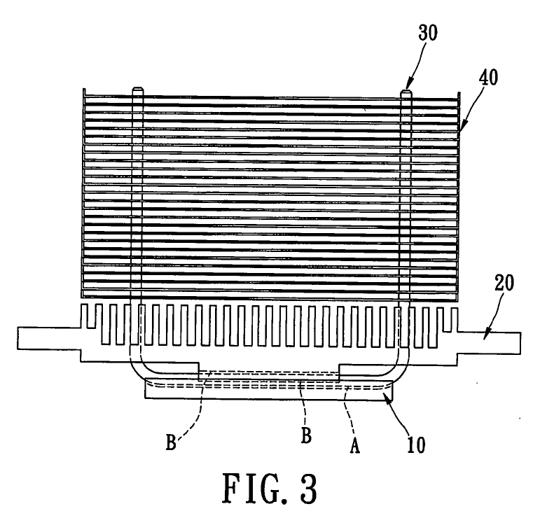

Referring to FIG. 3, the first embodiment of the present invention provides a coated heat sink, including: a copper base seat 10, an aluminum heat-dissipating seat 20, a plurality of heat pipes 30, a solder A, a heat-conducting adhesive glue B, and a plurality of heat-dissipating fins 40.

The aluminum heat-dissipating seat 20 is disposed on a top portion of the copper base seat 10, and the heat pipes 30 are also respectively disposed on the top portion of the copper base seat 10. Moreover, the solder A, which can be a tin paste, is respectively formed on contact surfaces among the copper base seat 10 and the heat pipes 30 for compactly joining the copper base seat 10 and the heat pipes 30 together, respectively. In addition, the heat-dissipating fins 40 are disposed over the aluminum heat-dissipating seat 20, and the heat-dissipating fins 40 are stacked together and compactly jointed with the heat pipes 30. Furthermore, the heat pipes 30 respectively penetrate the heat-dissipating fins 40. Because the copper base seat 10 is made of copper and the aluminum heat-dissipating seat 20 is made of aluminum, the heat-conducting adhesive glue B is respectively formed on contact surfaces between the copper base seat 10 and the aluminum heat-dissipating seat 20 and among the aluminum heat-dissipating seat 20 and the heat pipes 30 for compactly joining the copper base seat 10 and the aluminum heat-dissipating seat 20 together, and the aluminum heat-dissipating seat 20 and the heat pipes 30 together, respectively. Therefore, the present invention can not only omit the nickel-plating process of the prior art that is used to join the copper and the aluminum, but it also simplifies the process and thereby reduces the manufacturing cost due to the use of the heat-conducting adhesive glue B.

Furthermore, the heat-conducting adhesive glue B is an epoxy that has both good heat-conducting capabilities and good jointing capabilities for joining the aluminum and the copper. In addition, the viscosity of the heat-conducting adhesive glue B is between 1000 and 10000 cps/25□, and the thermal conductivity of the heat-conducting adhesive glue B is between 0.84 and 2.7 W/m·K. However, the above-mentioned viscosity value and thermal conductivity value should not be used to limit the present invention. Only the heat-conducting adhesive glue, having a good heat-conducting capability and being used to join the aluminum material and the copper material, is protected under the present invention.

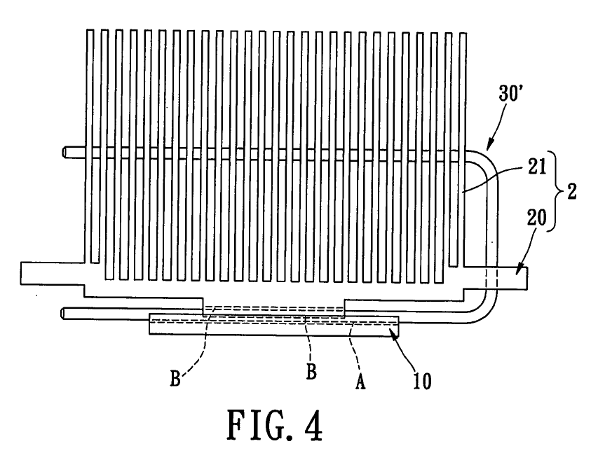

Referring to FIG. 4, the difference between the second embodiment and the first embodiment is that the second embodiment provides a heat-conducting unit 2. The heat-conducting unit 2 has an aluminum heat-dissipating seat 20 disposed on a top portion of the copper base seat 10 and a plurality of fins 21 disposed on a top side of the aluminum heat-dissipating seat 20. Moreover, the second embodiment provides a plurality of heat pipes 30′ bent into a C shape and respectively disposed on the top portion of the copper base seat 10 and compactly joining the fins 21 with each other.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A coated heat sink, comprising:
a copper base seat;
an aluminum heat-dissipating seat disposed on a top portion of the copper base seat;
a plurality of heat pipes respectively disposed on the top portion of the copper base seat;
a solder respectively formed on contact surfaces among the copper base seat and the heat pipes for compactly joining the copper base seat and the heat pipes together;
a heat-conducting adhesive glue respectively formed on contact surfaces between the copper base seat and the aluminum heat-dissipating seat and among the aluminum heat-dissipating seat and the heat pipes for compactly joining the copper base seat and the aluminum heat-dissipating seat together, and the aluminum heat-dissipating seat and the heat pipes together, respectively; and
a plurality of heat-dissipating fins disposed over the aluminum heat-dissipating seat, wherein the heat-dissipating fins are stacked together and compactly jointed with the heat pipes.

2. The coated heat sink as claimed in claim 1, wherein the heat pipes penetrate the heat-dissipating fins.

3. The coated heat sink as claimed in claim 1, wherein the heat-conducting adhesive glue is an epoxy.

4. The coated heat sink as claimed in claim 1, wherein the viscosity of the heat-conducting adhesive glue is between 1000 and 10000 cps/25□.

5. The coated heat sink as claimed in claim 1, wherein the thermal conductivity of the heat-conducting adhesive glue is between 0.84 and 2.7 W/m·K.

6. A coated heat sink, comprising:
a copper base seat;
a heat-conducting unit having an aluminum heat-dissipating seat disposed on a top portion of the copper base seat and a plurality of fins disposed on a top side of the aluminum heat-dissipating seat;
a plurality of heat pipes respectively disposed on the top portion of the copper base seat and compactly joining the fins together;
a solder respectively formed on contact surfaces among the copper base seat and the heat pipes for compactly joining the copper base seat and the heat pipes together; and
a heat-conducting adhesive glue respectively formed on contact surfaces between the copper base seat and the aluminum heat-dissipating seat and among the aluminum heat-dissipating seat and the heat pipes for compactly joining the copper base seat and the aluminum heat-dissipating seat together, and the aluminum heat-dissipating seat and the heat pipes together, respectively.

7. The coated heat sink as claimed in claim 6, wherein the heat pipes penetrate the heat-dissipating fins.

8. The coated heat sink as claimed in claim 6, wherein the heat-conducting adhesive glue is an epoxy.

9. The coated heat sink as claimed in claim 6, wherein the viscosity of the heat-conducting adhesive glue is between 1000 and 10000 cps/25□.

10. The coated heat sink as claimed in claim 6, wherein the thermal conductivity of the heat-conducting adhesive glue is between 0.84 and 2.7 W/m·K.
